(19) United States
(12) Patent Application Publication
(10) Pub. No.: US 2005/0052845 A1
(43) Pub. Date: Mar. 10, 2005

(54) Housing component for a device to be ventilated

(76) Inventor: Anton Breier, Friedberg (DE)

Correspondence Address: Mark C Comtois;Duane Morris, Suite 700, 1667 K Street NW, Washington, DC, 20006, US

(21) Appl. No.: 10/495,380

(22) PCT Filed: Nov. 7, 2002
(86) PCT No.: PCT/EP02/12439

(30) Foreign Application Priority Data
Nov. 14, 2001 (DE) 101 55 810.4

(51) Int. Cl. H05K 7/20

(52) U.S. Cl. 361/690; 312/223.2

(57) ABSTRACT

The invention relates to a housing component for a device to be ventilated, in particular an electrical or electronic device such as a mains piece with a planar wall section and a perforated aperture in the wall section. The aperture comprises several openings and webs between the openings. The webs are at least partly displaced relative to the surface of the wall section and preferably curved and thus elongated such that the total area of the openings defined by the webs is increased. The flow resistance of the perforated aperture, which is determined by the proportion of free surface to the base area of the aperture, is thus reduced.

### FIELD OF THE INVENTION

The present invention refers to a casing component for a piece of equipment to be ventilated which comprises a flat wall portion and a perforated opening in the wall portion which includes multiple apertures and lands located between the apertures.

### DESCRIPTION OF THE PRIOR ART

Numerous pieces of electrical and electronic equipment such as power supply units of all types, computers and other electronic devices must be cooled in many applications, fans being often used in the pieces of equipment to support cooling but in some devices cooling may also occur due to free convection.

To ensure a sufficient cooling of such equipment, the casings thereof generally include at least one perforated opening in one casing wall which comprises multiple apertures and lands located between the apertures to allow an air flow through the casing. Although an optimum ventilation of the casing could be achieved by a completely open opening, grille-like ventilation apertures are generally preferred, as they provide certain mechanical protection of the equipment arranged in the casing and, if metal casings are used, ensure electromagnetic screening of the electrical and electronic components. The apertures in the ventilation openings often have the shape of slits. The apertures should be the smaller, the higher the frequencies of the electromagnetic waves to be screened by the casing are.

### SUMMARY OF THE INVENTION

In the perforations generally used today to form ventilation openings in casing walls, it is extremely difficult to achieve a ratio of the open area to the total area of the perforated opening of more than 80% without endangering the mechanical stability and the electromagnetic screening action. It is therefore the object of the invention to develop a design for ventilation openings in casing walls of pieces of electrical or electronic equipment to be ventilated for their cooling which design allows a maximum air flow and at the same time ensures a sufficient electromagnetic screening of the equipment inside the casing.

This object is accomplished in a casing component of the above-mentioned type by at least partially staggering or offsetting the lands located between the apertures of the perforated opening against the plane of the wall portion. Preferably, the lands are bent toward the inside or outside and are thus extended.

An air flow through the perforated opening always involves a pressure drop. The invention achieves a minimization of this pressure drop and hence a maximization of the flow rates for the cooling of pieces of electrical and electronic equipment by increasing the open area in relation to the total area of the perforated opening by utilizing the third dimension for the perforated opening. As the lands located between the apertures are staggered or offset against the surface of the wall portion in which the opening is formed, specifically as they protrude from this surface and are bent in the form of a curved segment, elliptical segment, a wave or the like, their effective length increases, whereby the open area between the lands also increases. The total area of the passage apertures is determined by the dimensions of the respective lateral edges of the lands which limit the passage apertures and is, therefore, essentially determined by the linear dimensions of the lands. The base area of the entire perforated opening always remains constant. The design of the perforated ventilation opening according to the invention allows therefore the proportion of the open area in the base area to be increased, resulting in a reduced flow resistance. This allows to achieve a substantially identical air flow and hence a constant cooling action at a reduced fan speed, resulting both in energy savings and in a reduced noise emission. As required, the same fan speed can be used to implement an increased flow rate and hence an improved cooling action.

As discussed above, the net open area for the air flow is determined by the slits limited by the lands, as measured perpendicular to the effective surface of the lands, so that the bending results in an extension of the lands and hence in an increase in the surface area and hence in an increase in the open area. As, however, the base area (projection) of the perforated opening is constant as a whole, the proportion of the effective open area increases without an appreciable reduction in the width of the lands.

As discussed above, the casing of pieces of electrical and electronic equipment is also used to screen electromagnetic fields. To this end, the casing is generally made of metal. The design of the opening according to the invention allows to clearly increase the proportion of the effective open area without adversely effecting the electromagnetic screening action. The effective screening is determined by the largest “open diameter” in the casing wall. As the design of the perforated opening according to the invention does not change this largest open diameter, the invention has no adverse effect on the electromagnetic screening action.

The casing component according to the invention is preferably used in metal casings for pieces of electrical and electronic equipment, specifically for power supply units, computers and the like. It is useful in any cases in which electrical or electronic components are to be cooled by means of an air flow, the air flow being generated by a fan or by free convection. The design of the perforated opening according to the invention clearly reduces the flow resistance.

### BRIEF DESCRIPTION OF THE DRAWINGS

The invention will now be explained in greater detail with reference to embodiments thereof which are represented in the accompanying drawings, in which:

FIGS. 1 and 2 are perspective views of two casings having a perforated opening according to the prior art and a perforated opening according to the invention;

FIG. 3 is a schematic top view of a perforated opening according to the prior art;

FIG. 4 is a schematic cross-sectional view of the perforated opening of FIG. 3;

FIG. 5 is a schematic cross-sectional view of a perforated opening according to the invention; and

FIG. 6 is a diagram of the flow conditions in a piece of equipment ventilated by a ventilating fan for explaining the advantages of the invention.

### DETAILED DESCRIPTION OF THE PREFERRED EMBODIMENTS

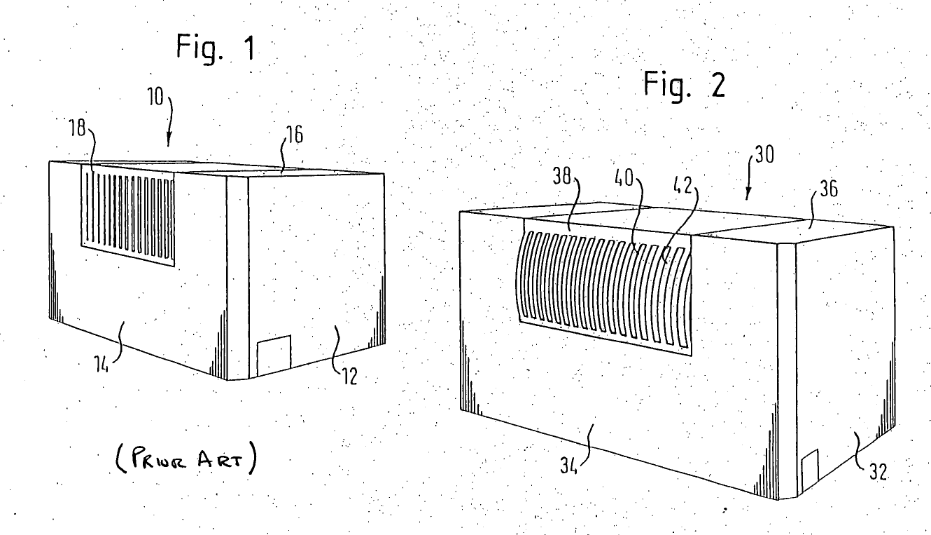

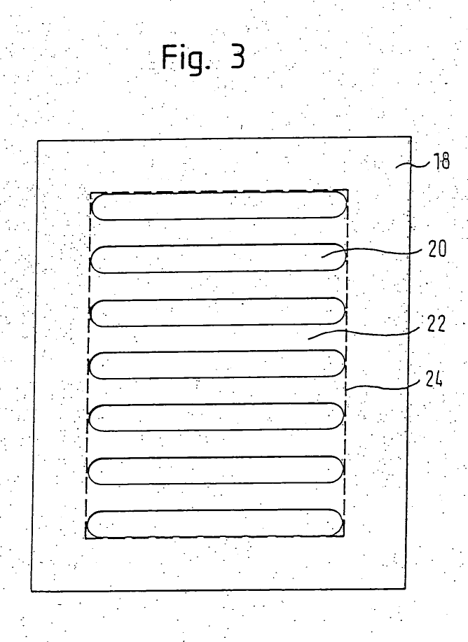

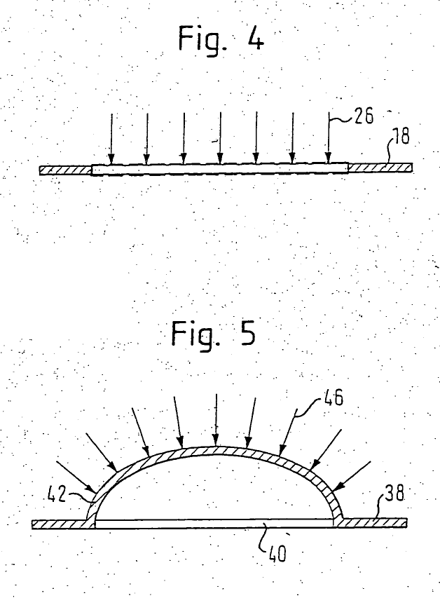

FIG. 1 schematically depicts an example of a casing 10 for any pieces of electrical and electronic equipment, which has a side panel 12, a back panel 14 (in the front of the drawing) and a cover panel 16. The casing comprises a perforated opening 18 formed as a flat metal plate having alternating elongated slits 20 and lands 22. A schematic top view of such a perforated opening according to the prior art, which has slits 20 and lands 22, is shown in FIG. 3. The lands 22 are also referred to as metal bridges. In FIG. 3, the total area of the perforated region is limited by a line 24. In FIG. 4, which depicts a schematic cross-sectional view of the passage plate 18 of FIG. 3, the open air passage surface limited by the lands 22 is schematically represented by arrows 26.

FIG. 2 shows a casing 30 for any piece of electrical or electronic equipment which has a side panel 32, a back panel 34 and a cover panel 36 according to the invention. In the back panel 34, a perforated passage plate 38 is arranged for ventilating the inside of the casing. The passage plate 38 comprises slits 40 limited by outwardly bent lands 42. FIG. 5 shows a schematic cross-sectional view of the passage plate 38 having a bent land 42, the effective area of the passage apertures limited by the bent lands 42 being schematically indicated by arrows 46.

Alternatively to the above embodiment, the lands 42 may also be bent in the direction of the inside of the casing or may be bent alternately toward the outside and inside. In addition, they may be bent in a form differing from the form shown, in a circular, angular, wave-like or in another form. Of importance in the design of the passage plate 38 according to the invention is the fact that the area of the passage apertures 20 is increased by the fact that the lands 42 limiting the apertures are at least partially staggered or offset outwardly from the plane of the wall portion in which the passage opening is located. Specifically, the lands 42 are extended by bending so that the area of the passage apertures 40 limited by the extension of the lands. The following comparative measurements were made using the two casings shown in FIGS. 1 and 2:
1. For the casing 10 shown in FIG. 1, a standard perforation was selected. The standard perforation had a perforated area of 75 mm×34.5 mm and was made up of a total of 16 slits and 15 lands having a length of 34.5 mm and a width of 3 mm. The width of the metal lands between the slits was 1.8 mm. The proportion of the open area in the total area is calculated to be 63%.
2. The casing 30 according to the invention, which is shown in FIG. 2, was provided with a passage plate 38 having the following features: The base area of the perforated opening is, like in the embodiment of FIG. 1, 75 mm×34.5 mm. This base surface is provided with a total of 16 slits and 15 lands having an effective length of 37 mm (in the example selected) and a width of 3 mm. The width of the metal lands was also 1.8 mm. The proportion of the open area in the total area is calculated to be approximately 68%.

The fan used was an NMB 3110 KL-04W-B60 type fan (12 V DC) which is capable of discharging a maximum static pressure of 45 Pa or a maximum throughput of 1.25 m³/min.
Ad. 1 For the standard perforation according to FIG. 1, an air velocity of 1.34 m/sec being equivalent to an air flow rate of 0.5388 m³/min was measured. Moreover, a fan speed of 3.627 rpm was measured at rated power.
Ad. 2 However, for the design of the opening 38 according to the invention as shown in FIG. 2, the air velocity was 1.44 m/sec being equivalent to a flow rate of 0.57 m³/min. The fan speed measured at the same power was 3.570 rpm.
3. To facilitate the evaluation of the effect of the passage plate according to the invention on the air flow in comparison with the passage plate according to the prior art, the air flow was additionally measured without the flow resistance produced by the perforated passage plate, by removing the back panel of the casing. The air velocity measured was 2.88 m/sec being equivalent to a flow rate of 1.14 m³/min. The fan speed measured at the same power was 3.710 rpm.

This comparative measurement shows the flow resistance of the remaining system including the pressure drop through the casing and the rear passage hole due to friction and the like. When the measurements are considered as a whole, the increase in the flow rate is about 6% when the design of the perforated opening according to the invention as specified under 2. above is used instead of the flat standard perforation. A closer analysis of the flow or pressure conditions on the perforated surfaces using flow simulation (CFD) reveals that a throughput increased by approx. 12% appears at the same pressure loss of 15 Pa or that a pressure loss reduced by 26% appears at the same throughput of 0.09 m³/sec if the perforation according to the above embodiment of the invention is used instead of the standard perforation. By a still stronger bending and extension of the lands 42 between the passage apertures, this factor can be further increased.

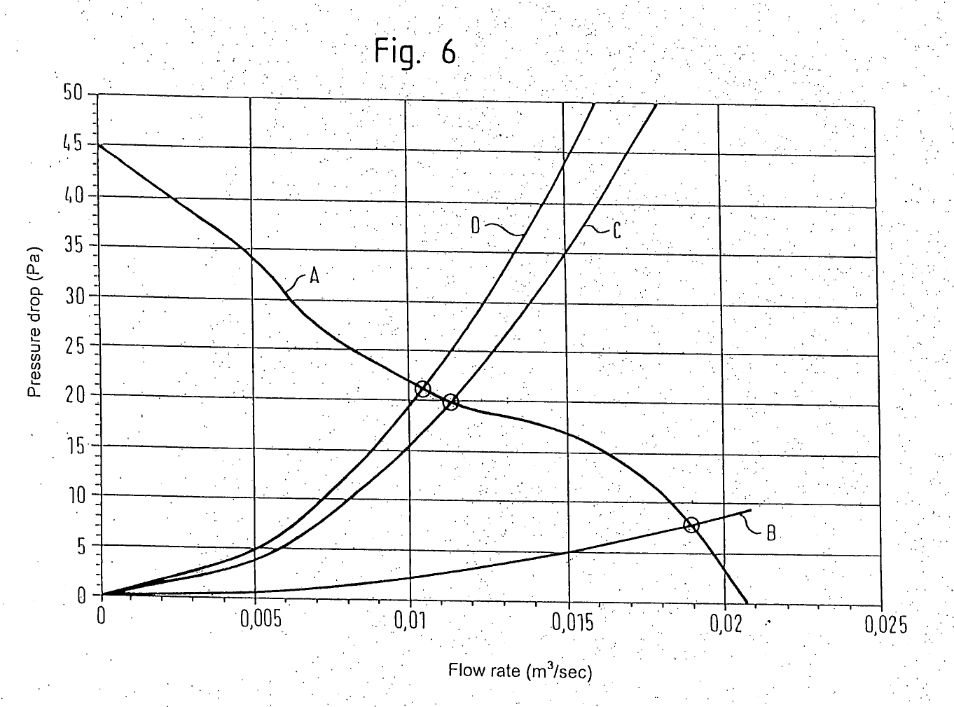

FIG. 6 shows a diagram of the flow curves in a piece of equipment cooled by a fan which was modified according to the embodiments described above. The curve marked with the letter A in FIG. 6 represents the pressure-flow rate characteristic of the fan used in the embodiment described. This curve A determines the operating points of the systems. Curve B indicates the case that the fan is operated in a casing whose back panel was removed; curve C indicates the case that the fan is operated in a casing comprising a passage opening according to the invention; and curve D indicates the case that the fan is operated in a casing comprising an opening having a standard perforation according to the prior art. The representation of FIG. 6 shows that the design of the passage opening according to the invention results in a higher flow rate at a lower pressure drop using the same fan. As explained above, the example studied results in a throughput increased by about 12% at the same pressure loss or in a pressure loss reduced by about 26% at the same throughput. It should be noted that another clear increase in these values can be achieved by a further extension of the lands of the passage plate and that the embodiments discussed here are first experimental arrangements of the applicant.

The features disclosed in the above description, in the claims and the drawings may be important, both separately and in any combination, to the implementation of the invention in the different embodiments thereof.

### LIST OF REFERENCE SYMBOLS

10 Casing
12 Side panel
14 Back panel
16 Cover panel
18 Passage plate
20 Slits
22 Lands
24 Line for marking the passage opening
26 Arrows for marking the effective passage area
30 Casing
32 Side panel
34 Back panel
36 Cover panel
38 Passage plate
40 Slits
42 Lands
46 Arrows for marking the effective passage area

1. A component of a casing (30) for ventilation comprising a flat wall portion (34) and a perforated opening (38) in the wall portion (34); the perforated opening having multiple apertures (40) and multiple lands (42) located between the apertures, wherein all lands (42) are at least partially offset against the flat wall portion (34).

2. The component according to claim 1, wherein the lands (42) are convex so as to protrude from the wall portion (34).

3. (Cancelled.)

4. The component according to claim 1, wherein the lands (42) are formed as an elliptical segment or have a wave-like shape.

5. The component according to claim 1, wherein a ratio of the apertures' (40) combined area to in the total area of the perforated opening (38) is at least 60%.

6. The component according to claim 1, wherein the flat wall portion (34) defines a two-dimensional or a three-dimensional surface.

7. (Cancelled.)

8. (Cancelled.)

9. A casing for a power supply unit cooled by a fan which casing has a component according to claim 1.

10. In a casing (10) for cooling an apparatus, the casing having side panels (12) and back panel (14), the back panel (14) having a perforated opening (18) defining lands (22) separating slits (20), the improvement comprising forming a perforated plate (38) with longer lands (42) and multiple slits (40) on the back panel (14).

11. The casing of claim 10, wherein the perforated plate (38) is concavo-convex.

12. The casing of claim 10, wherein the lands (42) are concavo-convex.

13. The ventilation of claim 10, wherein the lands (42) are about 5 to 15% longer as compared with the lands (22).

14. The ventilation of claim 10, wherein the lands have a wave-like shape.

15. A casing A casing for ventilation of electrical or electronic equipment comprising a casing (30) having a flat wall portion (34) and a perforated opening (38) in the wall portion (34), the opening having multiple apertures (40) and multiple lands (42) located between the apertures, wherein the lands (42) are at least partially offset against the plane of the wall portion (34).

16. A casing for a power supply unit cooled by a fan the casing (30) comprising a flat wall portion (34) and a perforated opening (38) in the wall portion (34), the perforated opening having multiple apertures (40) separated by multiple lands (42), wherein the lands (42) are at least partially offset against the plane of the wall portion (34).
